(19) United States
(12) Patent Application Publication
(10) Pub. No.: US 2022/0035245 A1
(43) Pub. Date: Feb. 3, 2022

(54) NANO IMPRINT STAMPS

(71) Applicant: Applied Materials, Inc., Santa Clara, CA (US)

(72) Inventors: Ian Matthew MCMACKIN, Mountain View, CA (US); Ludovic GODET, Sunnyvale, CA (US)

(21) Appl. No.: 17/034,004

(22) Filed: Sep. 28, 2020

Related U.S. Application Data
(60) Provisional application No. 63/059,809, filed on Jul. 31, 2020.

(51) Int. Cl. G03F 7/00; B29C 33/42; B29C 43/02

(52) U.S. Cl. CPC G03F 7/0002; B82Y 40/00; B29C 43/021; B29C 33/424

(57) ABSTRACT

An apparatus for manufacturing a nano-imprint lithography stamp from a master template stamp, including a stamp chuck configured to selectively secure a stamp backing material thereto, a master chuck configured to support a master template stamp, the master template stamp including a master pattern thereon, the master chuck configured to support the master template stamp in facing relationship to the stamp backing material when selectively secured to the stamp chuck, wherein the master template stamp includes an electromagnetic energy curable material on and in the master pattern, and the stamp chuck is configured and arranged to position a portion of the backing material thereon spaced therefrom and in contact with the electromagnetic energy curable material, and the stamp chuck is further configured to position the portion of the backing material in contact with the energy curable material, after it is cured, in contact with the stamp chuck.

### CROSS-REFERENCE TO RELATED APPLICATIONS

This application claims priority to U.S. Provisional Patent Application No. 63/059,809, filed Jul. 31, 2020, which is incorporated herein by reference in its entirety.

### BACKGROUND

### Field

The present disclosure relates to nano imprint lithography, more particularly to stamps used in nano imprint lithography and the manufacture thereof using a master template stamp. The patterned layer of the stamp corresponds to a pattern of a plurality of sub-micron optical device structures to be formed in a nanoimprint lithography (NIL) process.

### Description of the Related Art

Stamps used for nano imprint lithography are commonly manufactured by providing a backing material, such as glass, and depositing thereon a material which will form the patterned layer of the stamp. Then, a master template stamp is manually applied to the coated backing material, which can result in air pockets and other issues. Therefore, there is a need in the art for a more robust and repeatable methodology for the manufacture of nano imprint lithography stamps from a master template stamp.

### SUMMARY

Provided herein are apparatuses and methods for manufacturing nano imprint lithography stamps from master template stamps.

In one aspect, an apparatus for manufacturing a nano-imprint lithography stamp from a master template stamp, including a stamp chuck configured to selectively secure a stamp backing material thereto, a master chuck configured to support a master template stamp, the master template stamp including a master pattern thereon, the master chuck configured to support the master template stamp in facing relationship to the stamp backing material when selectively secured to the stamp chuck, wherein the master template stamp includes an electromagnetic energy curable material on and in the master pattern, and the stamp chuck is configured and arranged to position a portion of the backing material thereon spaced therefrom and in contact with the electromagnetic energy curable material, and the stamp chuck is further configured to position the portion of the backing material in contact with the energy curable material, after it is cured, in contact with the stamp chuck.

In another aspect, there is provided a method of manufacturing a nano-imprint lithography stamp from a master template stamp, including selectively securing a stamp backing material to a stamp chuck, positioning a master template stamp on a master chuck, the master template stamp including a master pattern thereon, the master chuck configured to support the master template stamp in facing relationship to the stamp backing material when it is selectively secured to the stamp chuck, including an electromagnetic energy curable material on and in the master pattern, positioning a portion of the backing material supported by the stamp chuck the portion spaced therefrom and in contact with the electromagnetic energy curable material and exposing the electromagnetic curable material to electromagnetic energy an curing the curable material to form a solid thereof, and positioning the portion of the backing material in contact with the energy curable material, after it is cured, in contact with the stamp chuck.

In another aspect, there is provided an apparatus for manufacturing a nano-imprint lithography stamp from a master template stamp, including a first stamp chuck configured to selectively secure a stamp backing material thereto, a first master chuck configured to support a cushion master, the cushion master including a blank pattern thereon, the first master chuck configured to support cushion master in facing relationship to the stamp backing material when selectively secured to the first stamp chuck, wherein the cushion master includes an electromagnetic energy curable material on and in the master blank pattern, and the first stamp chuck is configured and arranged to position a portion of the backing material thereon spaced therefrom and in contact with the electromagnetic energy curable material, and the first stamp chuck is further configured to position the portion of the backing material in contact with the energy curable material, after it is cured, in contact with the first stamp chuck, a second stamp chuck configured to selectively secure a stamp backing material thereto, a second master chuck configured to support a master template stamp, the master template stamp including a master pattern thereon, the second master chuck configured to support the master template stamp in facing relationship to the stamp backing material when selectively secured to the second stamp chuck, wherein the master template stamp includes an electromagnetic energy curable material on and in the master pattern, and the second stamp chuck is configured and arranged to position a portion of the backing material thereon spaced therefrom and in contact with the electromagnetic energy curable material, and the second stamp chuck is further configured to position the portion of the backing material in contact with the energy curable material, after it is cured, in contact with the second stamp chuck.

### BRIEF DESCRIPTION OF THE DRAWINGS

FIG. 1 is an isometric view of a nano imprint lithography stamp according to an embodiment.

FIG. 2 is a sectional view of the nano imprint lithography stamp of FIG. 1 at 2-2 according to an embodiment.

FIG. 3 is a side view of an apparatus for manufacturing a nano imprint lithography stamp from a master template stamp according to an embodiment.

FIG. 4 is a side view of an apparatus for manufacturing a nano imprint lithography stamp from a master template stamp using electromagnetic radiation according to an embodiment.

FIG. 4A is a side view of an apparatus for manufacturing a nano imprint lithography stamp from a master template stamp as the backing material begins to be released to contacts the stamp material according to an embodiment.

FIG. 4B is a side view of an apparatus for manufacturing a nano imprint lithography stamp from a master template stamp as the backing material is in the process of being released according to an embodiment.

FIG. 4C is a side view of an apparatus for manufacturing a nano imprint lithography stamp from a master template stamp as the backing material has been fully released.

FIG. 5 is a side view of an apparatus for manufacturing a nano imprint lithography stamp from a master template stamp after the stamp pattern has been formed

FIG. 6 is a flowchart showing a method for manufacturing a nano imprint lithography stamp from a master template stamp.

FIG. 7 is a side view of an apparatus for automating the manufacturing of a nano imprint lithography stamp from a master template stamp.

FIG. 7A is an isometric view of the apparatus for automating the manufacturing of a nano imprint lithography stamp from a master template stamp.

FIG. 8 is a flowchart showing a method for automating the manufacture of a nano imprint lithography stamp from a master template stamp.

FIG. 8A is a flowchart showing the steps for singulating a stamp from a roll of stamp glass after the method of FIG. 8 is completed.

FIG. 9 is a side view of an apparatus for automating the singulation of a nano imprint lithography stamp.

FIG. 10 is a side view of an apparatus for manufacturing a cushion for a nano imprint lithography stamp from a master template stamp.

FIG. 11 is a side view of an apparatus for manufacturing a cushion for a nano imprint lithography stamp from a master template stamp using electromagnetic radiation.

FIG. 12 is a side view of an apparatus for manufacturing a cushion for a nano imprint lithography stamp from a master template stamp after the cushion has been formed

FIG. 13 is a side view of an apparatus for manufacturing a cushioned nano imprint lithography stamp from a master template stamp.

FIG. 14 is a side view of an apparatus for manufacturing a cushioned nano imprint lithography stamp from a master template stamp using electromagnetic radiation.

FIG. 15 is a side view of an apparatus for manufacturing a cushioned nano imprint lithography stamp from a master template stamp after the cushioned stamp has been formed

FIGS. 16A and 16B are a flowchart showing a method for automating the manufacture of a cushioned nano imprint lithography stamp from a master template stamp.

FIG. 17 is a side view of an apparatus for automating the manufacture of a cushioned nano imprint lithography stamp from a master template stamp.

FIG. 18 is an isometric view of the apparatus for automating the manufacture of a cushioned nano imprint lithography stamp from a master template stamp.

### DETAILED DESCRIPTION

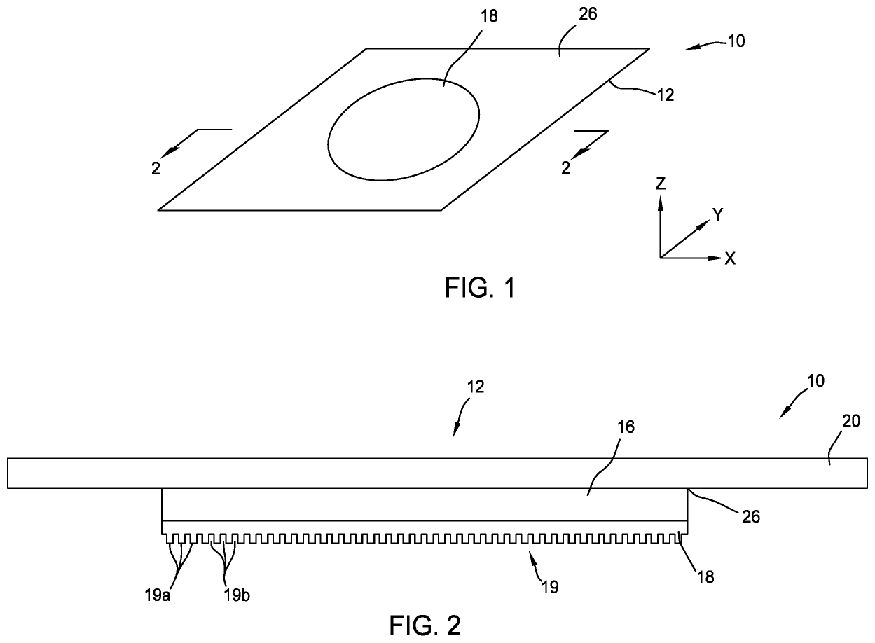

Referring initially to FIGS. 1 and 2, a stamp 10, useful for nano-imprint lithography, is shown, wherein the stamp 10 includes a backing material 12 provided for purposes of safe handling and protection of a patterned layer 18 thereon, and for mounting the backing material 12, with the patterned layer 18 thereon, to a process tool (not shown), to allow moving the patterned layer 18 into contact with a liquid or otherwise conformable material into which an impression of the pattern in the patterned layer 18 is to be made. Thus, the stamp 10 is used to imprint a reverse image of the patterned layer 18 into another material, for example by impressing the patterned layer 18 of the stamp 10 inwardly of a heat curable liquid, and cure the liquid with the patterned layer 18 of the stamp 10 extending inwardly thereof, to form the reverse pattern to that of the patterned layer 18 in the cured curable material. The patterned layer 18 of the stamp 10 corresponds to a pattern of a plurality of sub-micron optical device structures to be formed in a NIL process.

Here, the stamp 10, including the backing material 12 configured as a support substrate for the patterned layer 18, itself positioned on a front side of the backing material, are shown. Here, the backing material 12 is a thin glass sheet 20, on the order of 200 microns in thickness, but may be other materials having a suitable coefficient of thermal expansion close to matching that of an underlying substrate supporting a material layer, such as a curable liquid, into which the pattern of the patterned layer 18 is to be imprinted. The patterned layer 18 here comprises a cured Polydimethylsiloxane (PDMS) layer composed of a surface physically or chemically adhered to the backing material 12 on one side thereof and a pattern 19 of the patterned layer 18 embossed or imprinted in the opposite side thereof. The pattern 19 includes projections 19a and depressions 19b arrayed in a layout desired by the stamp 10 user.

In the cross section of the stamp 10 as shown in FIG. 2, the backing material 12, i.e., here glass 20, includes thereon a conformal layer 16 disposed between the patterned layer 18 and the backing material 12, and the conformal layer 16 is connected to the backing material 12 through an adhesive layer, here a primer layer 26 which is adhered to the backing material 12 prior to the forming of the patterned layer 18. The conformal layer 16, which is optional, is provided to allow the patterned layer 18 to be pressed inwardly of the material, for example a curable liquid, into which the reverse image of the patterned layer 18 is to be formed, for example if a particle or other disturbance is present in or on the material the pattern of the patterned layer 18 is being transferred into, and thus desirously is softer than the patterned layer 18. Here, where the patterned layer is PDMS, the conformal layer 16 may likewise be composed of cured PDMS having a different, softer, modulus of elasticity. However, as stated above, the presence of the conformal layer 16 in a stamp is optional.

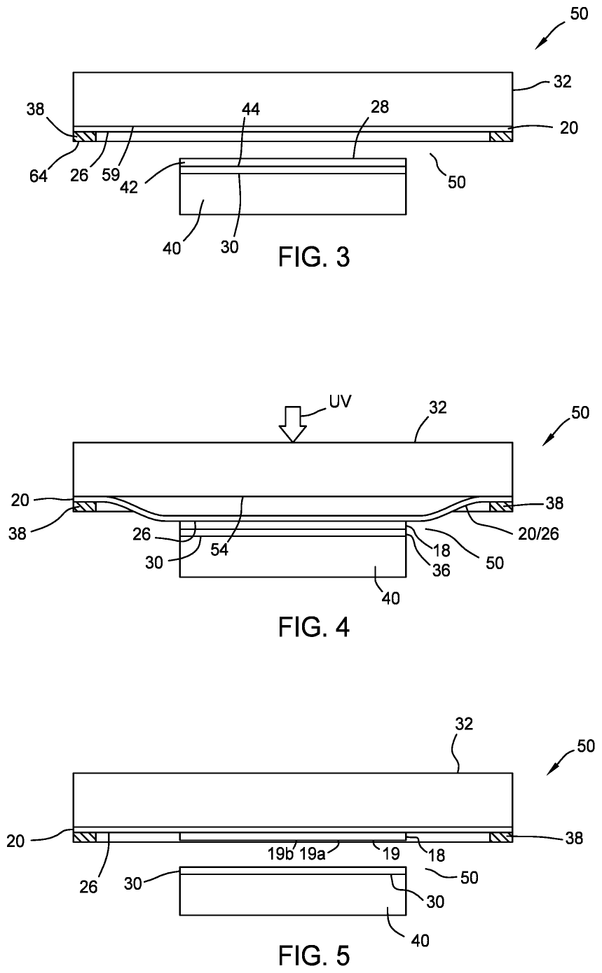

To manufacture the stamp 10, a master stamp template 30 (FIGS. 3 to 5) having a pattern to be ultimately formed on a production substrate (not shown) is prepared using traditional photolithography and patterned etching techniques, to form a desired pattern therein. The pattern may be etched into the underlying master substrate, for example a semiconductor substrate such as a single crystal silicon wafer, or other substrate, including a single crystal silicon wafer with a pre-patterned layer, into which the pattern will be etched, formed thereon. This master, having the ultimate pattern to be formed in the curable material on a substrate etched thereinto or into a layer formed thereon, is used to form the reverse of that pattern as the patterned layer 18 of the stamp 10, such that the stamp 10 is then used to form a reverse of the patterned layer 18 thereof in the curable layer of a production substrate, such the pattern of the master stamp template 30 is replicated in the cured material layer of the production substrate.

FIGS. 3 to 5 are schematic side views of representative equipment useful for manufacturing a stamp, including forming a patterned layer 18 having a desired pattern 19, the obverse of a pattern on a master stamp template 30, on a backing member 12 of a stamp 10, such as forming a patterned layer 18 on glass 20 as the backing member 12. In contrast to prior stamp forming operations, where the material of the patterned layer 18 is first formed on the backing material 12 such as the glass 20 and the master template 30 is pressed into the material on the glass 20 and the material on the glass 20 is cured to form the patterned layer 18, here, the material for the patterned layer 18 is first formed on the master template 30, and then transferred to the glass by the glass 20 being contacted with the material used to form the patterned layer 18 present on the master, and that material cured, and the backing material 12 with the patterned layer 18 remaining thereon forming the stamp 10 removed.

To perform this process of manufacture, a master template 30 having a master pattern 28 formed on one surface side thereof, is mounted to a master support chuck 40, such as by pulling vacuum through one or more passages opening at the master template mounting surface thereof. The master pattern 28 is a reverse pattern to that to be formed on the stamp 10, but is the pattern the stamp 10 will form in a layer on a production substrate when the stamp is used to imprint a pattern in a layer on a production substrate. Before mounting the master template to the master chuck 40, the surfaces of the master pattern 28 thereof are coated with a fluorinated self-aligning monolayer (SAM) which serves as a release layer 42, and with the pattern layer material 44 which here is an electromagnetic radiation, or light, curable liquid material.

The backing material 12, here the glass 20, is secured to a stamp chuck 32, such that the surface thereof having a primer layer 26 previously formed thereon is facing the master template chuck 40. With the master stamp template 30 on the master template chuck 40, the spacing between the master pattern 28 on the master stamp template 30 and the surface of the glass 20 facing the master stamp template 30 is on the order of less than one mm. Here, it is contemplated that the master chuck 40, the stamp chuck 32, or both, are moveable toward and away from each other, and may be mounted into, apparatus configured to change the position and orientation of the stamp chuck 32, master chuck 30, or both to allow placement and removal, as well as replacement with new versions of, the glass 20 (backing material 12) on the stamp chuck and the master stamp template 30 on the master chuck 40, and repositioning thereof as shown in FIG. 3.

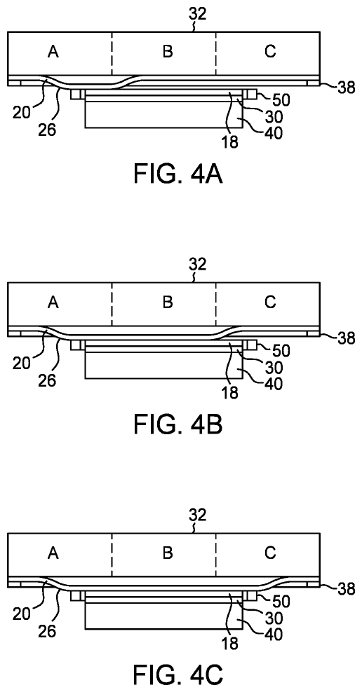

Here, to chuck the glass 20 (backing material 12) to the stamp chuck 32, the stamp chuck 32 includes a plurality of fluid passages 52a-c (FIGS. 4A-C) opening at the stamp glass chucking surface thereof, and a perimeter clamp 38 (Shown in section) configured to maintain the stamp glass chuck facing side of the perimeter of the glass 20 (backing material 12) against the surface of the stamp chuck.

FIG. 4 is a side view of the stamp forming apparatus 50 as the stamp glass 20 (backing material 12) is being contacted with the pattern layer material 44, i.e., the material within which the pattern 19 of the patterned layer 18 of FIG. 2 is formed, here a UV curable material such as PDMS. During the stamp 10 forming operation, the stamp glass 20 (backing material 12) is positioned with the patterned layer receiving side thereof, i.e., the side having the primer layer 26 thereon, facing and spaced from the patterned layer of the master stamp template 30 by about one mm or less as in FIG. 3, after which the patterned layer receiving portion of the stamp glass 20 (patterned layer 12) is actuated away from the stamp chuck 32 and into contact with the pattern material layer 44 as shown in FIG. 4. To move the stamp glass 20 from being located against the chucking surface of the stamp chuck 32 as shown in FIG. 3, to the position thereof in FIG. 4, the stamp glass chuck 38 has a plurality of pressure zones created by representative fluid passages 52a-c in the stamp chuck 32, here shown schematically as zones A, B and C in FIGS. 4A to 4C. Initially, as in FIG. 3, vacuum pressure, i.e., fluid pressure less than that of the surrounding ambient pressure, is present in the fluid passages 52a-c opening into the chucking surface of the stamp chuck 32 in all zones thereof, here schematically shown as three zones A, B and C fluidly connected to representative fluid passages 52a-c, but a greater or smaller number of zones may be used. Then, while vacuum is maintained in the passages 52b, c in communication with zones B and C, a pressure on the order of a few p.s.i is applied through the passages 52a of zone A to the backside, i.e., the stamp chuck 32 facing side, of the glass 20 (backing material 12), causing it to locally deform and thus causing the primer layer26 thereon contact the pattern layer material 44 on the master template 30 as shown in FIG. 4A. Then, while maintaining the positive pressure in zone A and the vacuum pressure in zone C, positive pressure is applied to the passages 52b in zone B to raise the pressure therein to that present in zone A to push the glass 20 away from the glass chucking surface of the glass chuck 32 and thus the primer layer 26 thereon into contact with the pattern layer material 44 in zone B as well, as shown in FIG. 4B. This paradigm is repeated in zone C, as shown in FIG. 4C, to bring the primer layer 26 on the glass 20 in all three of zones A, B and C into contact with the full expanse of the pattern layer material 44 on the master stamp template 30 with the same pressure applied in all of zones A, B and C.

A support ring 50 surrounds the master chuck 40 to limit the distance the glass 20 (backing material 12) can move in the direction of the master template 30, and to ensure relative parallelism between the master template facing surfaces of the glass 20 (backing material 12) when the perimeter of the glass 20 (backing material 12) radially outside of the pattern forming region, i.e., outside of the region where the patterned layer 18 is to be formed, comes into full contact with the ring 50 about the perimeter of the pattern forming region, with a reference plane of the master pattern 36. With the glass 20 (backing material 12) in this position and the primer layer 26 contacting the pattern material layer 44 throughout the pattern forming region of the glass 20 (backing material 12), UV electromagnetic energy as represented by arrow UV in FIG. 4, such as from an array of UV LED's 48 located behind (above in FIG. 4) the glass chuck 32, passes through the glass chuck 32 and the glass 20 (backing material 12) and primer layer 26 and is absorbed, at least in part, in the pattern layer material 44. Where the pattern layer material 44 is PDMS, it can be cured into a solid form. The patterned layer 18 with the pattern 19, the reverse of the master pattern 36 in the master stamp template 30, is now present in the cured PDMS.

To remove the glass 20, with the patterned layer 18 adhered thereto, the reverse of the sequence of FIGS. 4A to 4C is performed, such that the pressure in the fluid passages 52c in zone C is reduced to a sub ambient pressure while the pressure in zones A and B are maintained at above ambient pressure, the pressure in zone B is reduced to below atmospheric while zone C is maintained at a sub-ambient level, and then the passages 52a in Zone A are brought to the sub-ambient pressure of zones B and C. As a result, the patterned layer 12 secured to the glass 20 (backing material 12) via the primer layer 26 is peeled away from the master template 30, and as the primer 26 has an adhesive property, the cured PDMS forming the patterned layer 18 remains attached to the glass, as shown in FIG. 5, yielding a finished or manufactured stamp 10 having the reverse pattern of that of the master pattern of the master stamp template 30.

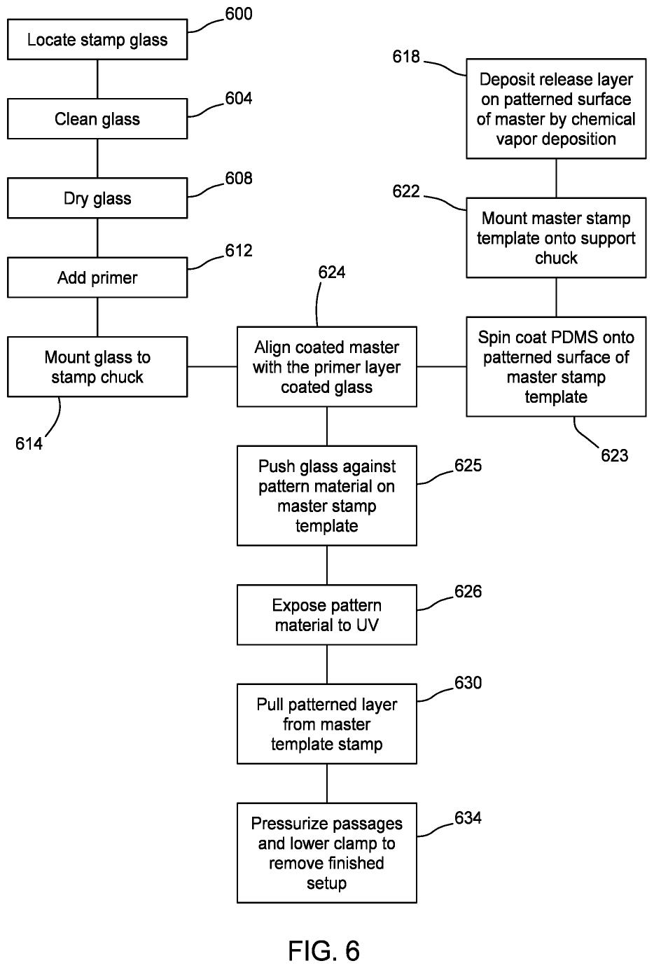

FIG. 6 is a flowchart showing a series of activities for manufacturing a stamp 10 according to the sequence of processes described with respect to FIGS. 3 to 5. Initially, the backing material 12 for a stamp 10 to be manufactured, and the preparation to configure a master stamp template 30 to form a patterned layer 18 on the backing material 12 of the stamp, are undertaken. Herein, the preparation of the glass 20 as the backing material 12 of the to be manufactured stamp 10 is described first, followed by a description of the preparation of the master stamp template 30 for manufacture of the stamp 10. However, these activities may be performed sequentially, with either the backing material 12, here glass 20, or the master stamp template 30 prepared first, they may be performed in parallel.

At Act 600, the backing material 12 of the stamp 10, here a thin glass sheet 20 on the order of 200 microns in thickness in the Z direction of FIG. 1 and having rectangular sides larger than the diameter of the pattered region 18 of the finished stamp in the X and Y directions of FIG. 1 is selected based on user preference, but the backing material 12 may be other materials having suitable coefficient of thermal expansion and physical properties useful for functioning as a backing material of a stamp 10 and capable of having electromagnetic energy pass therethrough. The glass is provided as a sheet and is cleaned, for example with a solvent such as isopropyl alcohol (IPA) followed by rinsing with deionized water in Act 606, and dried in Act 608. Drying may be accomplished by any process by which the water is removed without leaving behind contaminants or spotting of the glass, for example Marangoni cleaning where the glass is lifted out of the cleaning agent into an IPA vapor environment, spin rinse drying, or other methodologies as is known in the art. A primer layer 26 is then adhered to the clean glass surface in Act 612, on the surface side of the glass 20 where the patterned layer 18 of the stamp is to be formed. This can be accomplished by spraying the primer material onto the glass 20 (backing material 12), spin coating it thereon, or other methodologies. In Act 614, the glass 20 (backing material 12) is then mounted to a pressure chuck providing the stamp chuck 32, having fluid ports 52a-c opening at the backing material receiving surface 34 thereof, and the glass 20 (backing material 12) is held thereagainst by applying vacuum to those ports 52a-c and also physically clamping the perimeter of the stamp glass to the stamp chuck 32 with the clamp 38.

The master stamp template 30 is, at Act 618, loaded into the chemical vapor deposition chamber 54, and a SAM coating functioning as a release layer 42 to allow separation of the patterned layer 18 from the master pattern 28 is applied to the surfaces of the master pattern 28 thereof, such as by depositing a self-aligning monolayer (SAM) material thereon to form a self-aligned monolayer as the release layer 42 material. The self-aligned monolayer is preferable a fluorinated material having a significantly lower adhesion, per square centimeter of contact with the material of the patterned layer 18 of the stamp 10 to be manufactured than that patterned layer 28 has with the primer material of the primer layer 26. Then, in Act 622, the master stamp template 30 is mounted to a master chuck 40. A pattern layer material 44, in liquid form, is coated onto, and into the recesses of, the master pattern 36 of the master stamp template 30 at act 632 using a spin coater 55. This pattern layer material 44 may be coated onto the master stamp before or after the master stamp template 30 is mounted to the master chuck 40. For example, a UV curable liquid, for example Polydimethylsiloxane (PDMS), is spin coated on the master pattern 36 to form the pattern material 44 into which the patterned layer 18 will be formed. After spin coating of the PDMS material on the surfaces of the master pattern 36 is performed, the master stamp template 30 and the stamp glass 20 with the primer 26 thereon are located in facing alignment in Act 624 wherein the primer 26 coated surface of the stamp glass 20 faces the PDMS layer on the master stamp template 30, and the glass 20 is vacuum chucked to the stamp chuck 32.

Thereafter, at Act 625, one side, in the X or Y direction of FIG. 1, of the glass 20 (backing material 12) is pushed away from the stamp chuck 32 by pressurizing the fluid openings 52a in the stamp chuck 32 in zone A thereof, followed by applying pressure to zone B while maintaining a pushing pressure in zone A, followed by pressurizing the openings in Zone C of the glass chuck while maintaining the pushing pressure in zones A and B, as shown in FIGS. 4A to 4C. As discussed herein, the progress of the surface of the primer coated side of the glass toward the master is limited by the spacing ring 50. With the primer coated surface of the glass 20 (backing material 12) in contact with the liquid PDMS of the pattern material layer 44, UV light is applied to the liquid PDMS pattern material layer 44 through the stamp chuck 32 and the glass 20 (backing material 12), to cure the PDMS in Act 626 into a solid material. Thereafter, in Act 634, the glass 20 (backing material 12) with the PDMS cured thereon and now forming the patterned layer 18, is pulled away from the master stamp template 30, in the re verse sequence of FIGS. 4A to 4C, where vacuum is sequentially applied first in zone C, then zone B and finally in Zone A in Act 630. As the primer 26 has greater adherence to the cured PDMS of the patterned layer 18 than does the SAM layer serving as the release layer 42 on the master stamp template 30, the PDMS, now cured and forming the patterned layer 18 of the stamp 10, maintains adherence to the glass 20 (backing material 12) as the glass 20 (backing material 12) is pulled away from the master30. Then, pressure is applied to the passages 52a-d and the perimeter clamp 38 is lowered to release the finished stamp 10 from the stamp chuck 32.

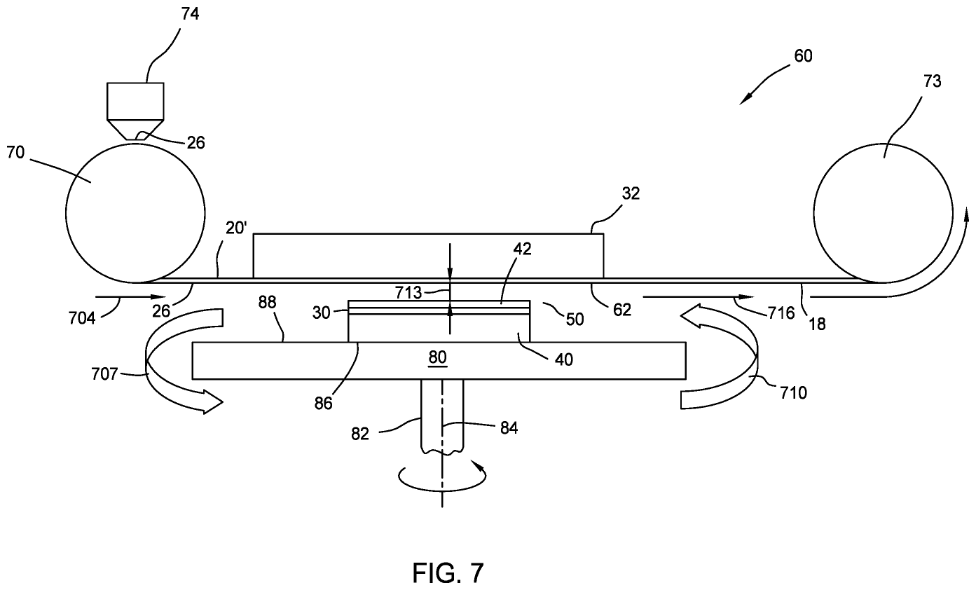

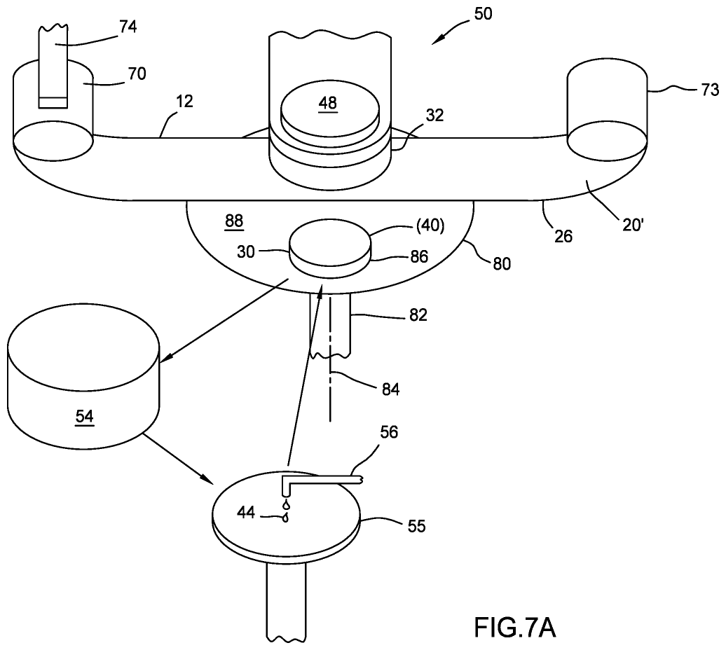

FIG. 7 is a side schematic view of an automated stamp manufacturing apparatus 60, and FIG. 7A is an isometric view of the apparatus 50. In contrast to the stamp manufacturing apparatus 50 of FIGS. 3 to 5, here, the backing material 12, here thin stamp glass 20′ having a thickness on the order of 200 microns, is provided on a backing material supply or stock roll 70 wherein a length of glass 20′ (backing material 12′) equal to at least several pieces of glass 20 of a finished stamp 10 in the X or Y directions of FIG. 1, and, after a pattern layer is formed on discrete portions 62 thereof, the length glass 20′ (backing material 12′) moved toward and onto a take up roll 73. Once the patterned layer 18 is formed on the strip or length of glass 20′, a pre-stamp 10′ is formed, which can later be cut from the length of glass 20′ (backing material 12′) to form a finished stamp 10 for use in nano imprint lithography. To manufacture the pre-stamp 10′, a master chuck 40 for holding a master stamp template 30, and the stamp chuck 32, configured for chucking the length of glass 30′ directly between the stamp chuck 32 and the master chuck 30 thereto, having the fluid passages 52a-c and operation described herein with regard to FIGS. 3 to 5, are provided between the stock roll 70 and take up roll 73 such that the length of glass 20′ (backing material 12′) passes therebetween. Here, to form a pre-stamp 10′, the stock roll 70 is rotated to unroll therefrom a discrete amount or discrete portion 62 of the strip or length of glass 20′, the discrete portion 62 having a dimension, in the direction between the stock roll 70 and take up roll 73 slightly larger than the side dimensions of a finished stamp 10. For example, if the glass 20 (backing material 12) of a finished stamp of FIGS. 1 and 2 is 15 inches long on each side thereof in the X and the Y directions, a discrete portion 62 of the length of glass 20′ (backing material 12′) greater than 15 inches is unrolled from the stock roll 70, and taken up by the take up roll 73, such that a new or fresh discrete portion 62 of the strip or length of glass 20′ (backing material 12′) is positioned between the master chuck 40 and the stamp chuck 32. Here the glass 0′ also has a dimension, in the direction perpendicular to the length thereof 2 extending from the stock roll 70, of 15 inches. The strip or length of glass 20′ (backing material 12′) on the stock roll 70 is preferably pre-cleaned before being rolled up to provide the stock roll 70, and as the glass 20′ (backing material 12′) of the stock roll 70 is unrolled, a primer application device 74 such as a sprayer bar extending across the width of the glass 20′ (backing material 12′) (in the depth direction of FIG. 7) applies a primer material on the clean portion of the length of glass 20′ (backing material 12′) unwound therefrom to form the primer layer 26 as it passes thereunder. Optionally, prior to being coated with the material forming the primer layer 26, the discrete portion 62 of the length of glass 20′ (backing material 12′) dispensed from the stock roll 70 can be cleaned and dried as it is unwound from the stock roll 70. Then, the primer application device 74 applies the primer material to form the primer layer 26 to the just cleaned discrete portion 62 of the length of glass 20′ (backing material 12′) taken from the stock roll 70. Here, the distance from where the glass 20′ (backing material 12′) leaves the stock roll 70 to the location of the stamp chuck 32 and facing master chuck 30 is greater than the length, in the roll to roll direction of the portion of glass 20′ (backing material 12′) used to manufacture a pre-stamp 10′, as one portion of the glass 20′ (backing material 12′) is cleaned and coated, or simply coated, with the primer material, to form the primer layer 26, the previously primer material coated portion of the glass 20′ (backing material 12′) is moved between the stamp chuck 32 and the master chuck 40.

As with the stamp forming apparatus 50 described with respect to FIGS. 3 to 5 hereof, after each use of the master stamp template 30 to imprint a pattern to form a patterned layer 18, the master must be washed, recoated with the release layer, and repositioned for reuse to form another patterned layer 18. Here, that is accomplished by mechanically moving the master stamp template 30, or the master chuck 40 with the master stamp template 30 thereon, to the side of the location of the stamp chuck 32, such as by mounting the master stamp template 30 or the master chuck 40 on a turntable 80 and rotating the turntable 80 between a location where the stamp master stamp template 30 is positioned facing the stamp chuck 32 and a location where the stamp master stamp template 30 is spaced from the stamp chuck 32 and somewhat to the side thereof to enable removal of the stamp chuck 30 without physical or mechanical interference with the stamp chuck 32 during the removal of the stamp chuck 30 as shown in FIG. 7A. For example, a turntable 80 having one or more master receiving stations 86 thereon or in a stamp chuck 32 receiving surface 88 thereof, can receive a master stamp template 30, or a master chuck 40, at each receiving station. By rotating a shaft 82 connected to the center of the turntable 80 at the center thereof, about a centerline 84 of the shaft, the master receiving stations 86 can be moved in arcs to be positioned below and facing the stamp chuck 32 and stopped thereat for the process of forming the patterned layer 18 on the discrete portion 62 of the glass 20′ (backing material 12′) located between that master stamp template 30 and the stamp chuck, and then the turntable can be indexed in another rotational motion about the axis 84 to position and fix an additional master chuck 40 to face the stamp chuck 32. Thus, by providing a plurality of identical master stamps 30, as each master stamp template 30 is used to form a patterned 18 layer and moved away from the location of the stamp chuck 32, a new master stamp template 30, with a release layer 42 formed thereon in a chemical vapor deposition chamber 54 (shown schematically) and a layer of pattern forming material 44 applied thereover by spin coating on a spin chuck 55 with a liquid pattern layer material dispenser 56, is indexed by the turntable 80 to be positioned facing, and properly aligned to, the facing surface of the stamp chuck 32.

Once a master stamp template 30, with a release layer 42 and a pattern material layer 44 thereon, is indexed by the turntable 80 to be positioned facing, and properly aligned to, the facing surface of the stamp chuck 32 and a discrete portion 62 of the primer coated glass 20′ (backing material 12′) is moved into the stamp forming apparatus 60 with the primer layer 26 facing toward the master chuck 40, the apparatus is ready to form a patterned layer 18 on the discrete portion 62 of the glass 20′ underlying the stamp chuck 32. At the same time, a master stamp template 30 which was just used to form a patterned layer 18 and which was moved away from the location between the stamp chuck 32 by the turntable 80 is removed from a master chuck 40 on the turntable 80 of the stamp forming apparatus, such as manually or by an automated methodology such as with a robot. A clean, and coated with the release layer 42 and pattern forming material 44, master stamp template 30 is then located on the open master chuck 40. Alternatively, the just removed master stamp template 30 could be cleaned, recoated with the release layer 42, coated with a fresh pattern material layer 44 and placed on the open master chuck 40 from which it had been removed. After the new or previous master stamp template 30, coated with a new release layer 42 and a new pattern material layer 44 is put into the stamp forming apparatus, it may be moved to the location facing the stamp chuck 32, a new portion of the glass 20′ (backing material 20′) positioned therebetween, and a new stamp is created as described herein with respect to FIGS. 3 to 6.

In contrast to the manufacture of the stamp 10 in FIGS. 3 to 6, here the stamp preform 10′ is formed by first applying vacuum to the passages 52a-c in the stamp chuck 32 to pull the discrete portion 62 of the glass 20′(backing material 12′) on which the patterned layer 18 is to be formed against the glass chucking surface thereof, and the perimeter clamp 38 is pushed from a location below the portion of the glass 20′ (backing material 20′) to extend along, and press, the portion of the glass 20′ (backing material 20′) on which the patterned layer is to be formed against the perimeter of the stamp chuck 32. Thereafter, the manufacture of the patterned layer 18 follows a similar sequence, wherein the paradigm for positioning the primer coated surface of the glass, here glass 20′ (backing material 20′) in contact with the pattern material layer 44 in liquid form, the curing by directing UV energy or light through the stamp chuck 32 and the glass 20′ (backing material 20′) into the pattern material layer 44 to cure it, and the sequence of pulling the glass, here glass 20′ (backing material 20′) away from the master 20 with the patterned material layer 18 adhered thereto are performed.

Once the portion of the glass 20′ (backing material 20′) just having the patterned layer formed thereon is pulled from the master 20, vacuum in the passages 52a-c are relieved, the perimeter clamp 38 is retracted, a slightly positive, with respect to ambient, pressure is applied to the passages 52a-c to ensure the glass 20′ can move with respect to the stamp chuck 32, and the stock roll 70 and take up roll 73 moved to index a new discrete portion 62 of the glass 20′ (backing material 20′) to the position between the stamp chuck 32 and the current, or expected, location of a master 20 facing the stamp chuck 32, and the process repeated. The process of indexing the portion of the glass 20′ (backing material 12′), cleaning and recoating the master stamps 30, and positioning them to face the stamp chuck 32, is repeated until an entire roll of glass 20′ is coated with patterned layers 18, after which a new roll of glass 20 (backing material 12′) can be loaded into the apparatus and the process repeated. As stamp pre-forms 10′ are formed, and the stock roll 70 and take up roll 73 moved to index a new portion of the glass 20′ (backing material 20′) to the position between the stamp chuck 32 and the current, or expected, location of a master 20 facing the stamp chuck 32, the stamp pre-forms 10′ will become rolled into the take up roll 73 which can be later rolled out, and individual stamps 10 formed therefrom.

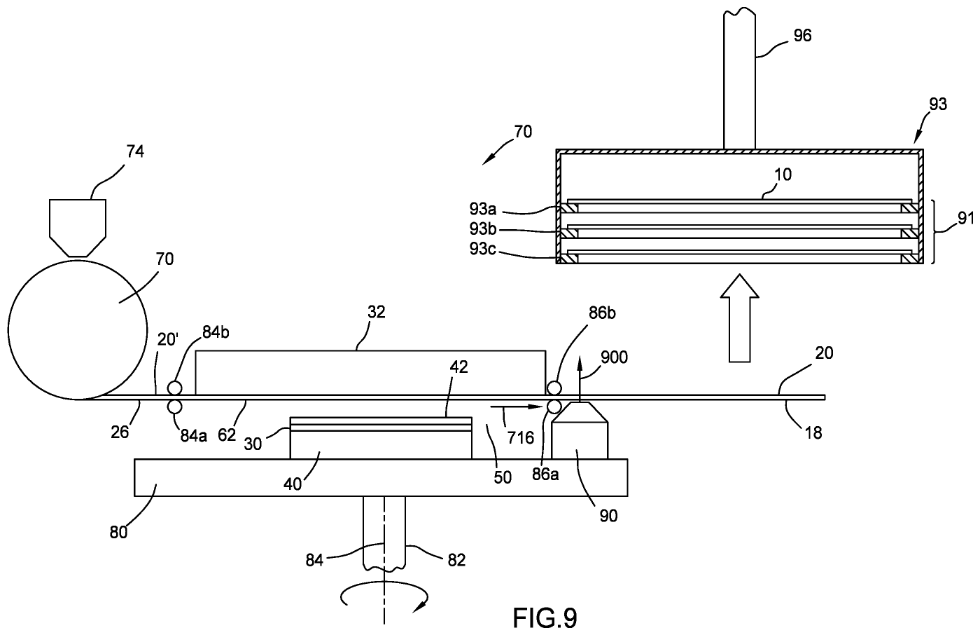

FIG. 9 is a side view of another alternative automated stamp forming apparatus 70 hereof. In contrast to the stamp manufacturing apparatus 60 of FIG. 7, here the pre-stamps 10′ are separated or singulated from the stamp glass 20′ by a stamp separation device 90 located, in a glass 20′(backing material 20′) feed direction downstream of the master chuck 40 and stamp chuck 32 by a distance sufficient for a singulation device to be present to sever the glass 12′ (backing material 20′) along a line generally perpendicular to the feed direction go the glass 20′ (backing material 12′). Once the patterned layer 18 is formed on a desired discrete portion 62 of the length of glass 20′(backing material 20′) dispensed from the stock roll 70 as shown and described with respect to FIG. 7, a pre-stamp 10′ comprising the portion of glass 20′ (backing material 12′) is formed and is still attached to the length or strip of glass 20′ (backing material 12′) being dispensed from, the stock roll 70, with the primer layer 26 and the patterned layer 18 thereon, which is thereafter cut from the length of glass 20′ (backing material 12′) to form a finished stamp 10.

To manufacture this pre-stamp 10′, master chuck 40 for holding a stamp master stamp template 30, and the stamp chuck 32, configured for chucking the length of glass 30′ directly between the stamp chuck 32 and the master chuck 30 thereto, having the fluid passages and operation described herein with respect to FIGS. 3 to 5, are provided to receive discrete portions 62 of the glass 20′ (backing material 12′) dispensed or pulled from the stock roll 70 such that a length of glass 20′ (backing material 12′) is disposed therebetween As no take up roll 73 is here provided, to position the glass 20′ (backing material 12′) dispensed from the stock roller 70, a first pair of rollers 84a, b is disposed, one roller on each side of the glass 20′ (backing material 12′), adjacent to the stock roll 70 side of the master chuck 40, and a second pair of rollers 86a, b, one roller of which is on either side of the glass 20′, is located such that the master chuck 40 and stamp chuck 32 is disposed between the second pair of rollers 86a,b and the first pair of rollers 84a, b. Each of the rollers 84a, b and 86a, b of the first pair of rollers 84a, b and second pair of rollers 86a,b extend across the width direction of the glass 20′ (backing material 12′), i.e., in the direction into the page of FIG. 9, and at least one of the first pair of rollers 84a, b and one of the second pair of rollers 86a,b is positively rotated such as by a servo motor, to both actively position the portion of the glass 20′ (backing material 12′) on which the patterned layer 18 is to be formed between the master chuck 40 and the stamp chuck 32, and to maintain sufficient tension on the portion of the glass 20′ (backing material 12′) extending therebetween to be maintained in a sufficiently close to the flat plane to prevent scraping thereof against a master stamp template 30 on the master chuck 40 or the stamp chuck 32 during glass 20′ (backing material 12′) movement. Thus, in this version of the stamp manufacturing apparatus 70, to form a pre-stamp 10′ the stock roll 70 is rotated to unroll therefrom a discrete portion 62 of the length or strip of glass 20′ (backing material 20′), the discrete portion 62 having a dimension, in the direction between the stock roll 70 and the second pair of rollers 86a, b, which is slightly larger than the side dimensions of a finished stamp 10. For example, if the glass 20 (backing material 12) of a finished stamp is 15 inches long on each side thereof in the X and the Y directions of FIG. 1, a discrete portion of the length of glass 20′ (backing material 12′) greater than 15 inches is unrolled from the stock roll 70, and taken up by the first and second pairs of rollers 84a, b, 86a, b. Here the glass 20′ also has a dimension, in the direction perpendicular to the length thereof extending from the stock roll 70, of 15 inches. As a result, a new or fresh discrete portion 62 of the length of glass 20′ (backing material 12′) is positioned between the master chuck 40 and the stamp chuck 32. The length of glass 20′ (backing material 12′) on the stock roll is preferably pre-cleaned before being rolled up to provide the stock roll 70, and as the glass' (backing material 12′) of the stock roll 70 is unrolled, a primer application device 74 such as a sprayer bar extending across the width of the glass 20′ (backing material 12′) (in the depth direction of FIG. 9) applies a primer material on the clean portion of the length of glass 20′ (backing material 12′) unwound therefrom to form the primer layer 26 as it passes thereunder. Optionally, prior to being coated with the material forming the primer layer 26, the portion of the length of glass 20′ (backing material 12′) can be cleaned and dried as it is unwound from the stock roll 70. Then, the primer application device 74 applies the primer material to form the primer layer 26 to the just cleaned portion of the length of glass 20′ (backing material 12′) taken from the stock roll 70. Here, the distance from where the glass 20′ (backing material 12′) leaves the stock roll 70 to the location of the stamp chuck 32 and facing master chuck 30 is greater than the length, in the roll to roll direction of the portion of glass 20′ (backing material 12′) used to manufacture a pre-stamp 10′, as one portion of the glass 20′ (backing material 12′) is cleaned and coated, or simply coated, with the primer material, the previously primer material coated portion of the glass 20′ (backing material 12′) is moved between the stamp chuck 32 and the master chuck 40 by the unwinding of the stock roll 70 and first and second pairs of rollers 84a, b, 86a, b.

As with the device described with respect to FIGS. 3 to 5 hereof, after each use of the master stamp template 30 to imprint a pattern to form a patterned layer 18, the master must be washed, recoated with the release layer, and repositioned for reuse to form another patterned layer 18. Here, this is accomplished by using the same methodologies as described herein with respect to FIG. 7.

In contrast to the manufacture of the stamp 10 in FIGS. 3 to 6, here a stamp preform 10′ is formed by first applying vacuum to the passages 52a, b in the stamp chuck 32 to pull the portion of the glass 20′(backing material 12′) on which the backing layer 18 is to be formed and which was positioned thereunder by the movements of the stock roll 70 and the rollers thereagainst, and the perimeter clamp 38 is pushed from a location below this portion of the glass 20′ (backing material 20′) to extend along, and press, the perimeter of the discrete portion 62 of the glass 20′ (backing material 20′) on which the patterned layer 18 is to be formed against the perimeter of the stamp chuck 32. Thereafter, the manufacture of the patterned layer 18 follows a similar sequence as that shown and described with respect to FIGS. 3 to 6, wherein the paradigm for positioning the primer coated surface of the glass, here glass 20′ (backing material 20′) in contact with the pattern material layer 44 in liquid form, the curing of the pattern material layer 44 by directing UV energy or light through the stamp chuck 32 and the glass 20′ (backing material 20′) into the pattern material layer 44 to cure it, and the sequence of pulling the glass, here glass 20′ (backing material 20′) away from the master 20 with the patterned material layer 18 adhered thereto are performed.

Once the portion of the glass 20′ (backing material 20′) just having the patterned layer formed thereon is pulled from the master 20, the perimeter clamp 38 is withdrawn and the vacuum in the passages 52a, b of the stamp chuck 32 are relieved and a slight positive pressure, compared to ambient pressure surrounding the stamp chuck 32, to help release the glass 20′ (backing material 20′) from the glass 20′ (backing material 20′) facing surface of the stamp chuck 32, and the stock roll 70 and first and second rollers 84a, b and 86a, b rotated to index a new or fresh, primer layer 26 coated discrete portion 62 of the glass 20′ (backing material 20′) to the position between the stamp chuck 32 and the current, or expected, location of a master 20 facing the stamp chuck 32. The indexing of the discrete portion 62 of the glass 20′ (backing material 12′), cleaning and recoating a master stamp template 30, and positioning a master stamp template 30 to face the stamp chuck 32, and the forming of the patterned layer 18 on portions of the glass 20′(backing material 12′) is repeated until an entire roll of glass 20′ (backing material 12′) is depleted, after which a new roll of glass 20′ (backing material 12′) can be loaded into the apparatus and the process repeated.

As stamp pre-forms 10′ are formed, and the stock roll 70 and rollers 84a, b, 86a, b rotated to index a new portion of the glass 20′ (backing material 20′) to the position between the stamp chuck 32 and the current, or expected, location of a master 20 facing the stamp chuck 32, the stamp pre-forms 10′ are located to the downstream, in the glass 20′ (backing material 20′) feed direction, of a stamp separation device 90. The rotation of the stock roll 70 and rollers positions the stamp preforms 10′ to be positioned such that the end of the glass 20′ (backing material 20′) forming the leading edge of the stamp preform 10′ is the desired sidewall length of a finished stamp 10 from the location where a stamp 10 is singulated from the length of glass 20′ (backing material 20′) facing surface of the stamp chuck 32 by cutting though or scoring and breaking along a line glass 20′ (backing material 20′) to singulate a stamp 10 therefrom. The stamp preform 10 is held in place by a table (not shown) or other support mechanism, and cut with the stamp separation device 90, for example a laser, by scoring the glass 20′ (backing material 20′) across the length direction thereof and then bending it along the score, or other mechanisms such as by use of a diamond cutting wheel or other cutting device. The now separated stamp 10 is moved by a movable robot arm 92 and placed just above a cassette holding portion of a cassette apparatus, for example a cassette 93 with shelves 93a-c, connected to a lift rod 96. The shelves 93a-c are equally spaced opposed side shelves aligned to receive a stamp 10 with room between the shelves 93a-c sufficient to allow the movable robotic arm 92 access. Once a stamp 10 is located above, for example shelf 93a, the lift rod 96 then moves the cassette 93, and thus shelf 93a upwardly to locate the stamp 10 on shelf 93a and position shelf 93b just below where the next stamp 10 will be positioned by the robotic arm 92.

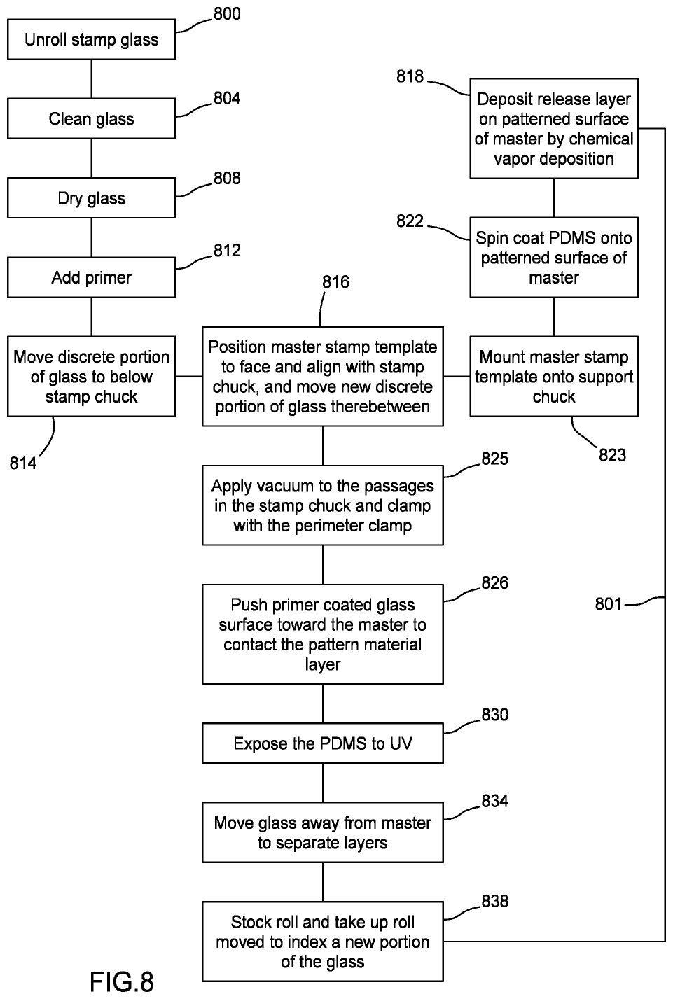

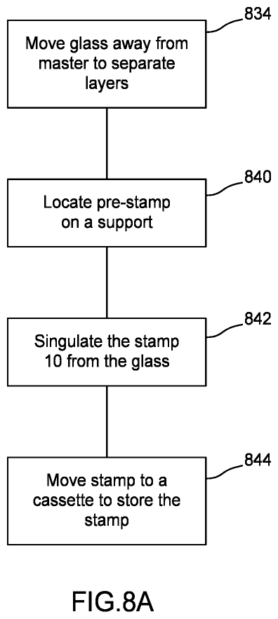

FIG. 8 is a flowchart showing a series of activities for manufacturing a stamp 10 according to the sequence of processes and the apparatus described with respect to FIG. 7. Here the backing material 12, here thin stamp glass 20′ (backing material 12′) having a thickness on the order of 200 microns, is provided on a backing material supply or stock roll 70 wherein a length of glass 20′ (backing material 12′) equal to at least several discrete portions 62 of glass 20 of a finished stamp 10 in the X or Y directions of FIG. 1, and, after a pattern layer is formed on the discrete portions 62 thereof, the length or strip of glass 20′ (backing material 12′) is moved toward a take up roll 73. Once the patterned layer 18 is formed on a discrete portion 62 of the glass 20′, a pre-stamp 10′ is formed, which can later be cut from the length of glass 20′ (backing material 12′) to form a stamp 10. To manufacture the pre-stamp 10′, the master chuck 40 for holding a stamp master stamp template 30, and the stamp chuck 32, configured for chucking the length of glass 30′ directly between the stamp chuck 32 and the master chuck 30 thereto, having the fluid passages 52a-c and operation described herein with respect to FIGS. 3 to 5, are provided between the stock roll 70 and take up roll 73 such that the length of glass 20′ (backing material 12′) passes therebetween Here, to form a pre-stamp 10′, the stock roll 70 is rotated in Act 800 to unroll therefrom a discrete amount or a discrete portion 62 of the length of glass 20, the portion having a dimension, in the direction between the stock roll 70 and take up roll 73 slightly larger than the side dimensions of a finished stamp 10, and the glass 20′ (backing material 12′) has a similar dimension in the direction perpendicular thereto. The length or strip of glass 20′ (backing material 12′) on the stock roll is pre-cleaned and dried before being rolled up to provide the stock roll 70, and as the stock roll 70 is unrolled in Act 800, a primer application device 74 such as a sprayer bar extending across the width of the glass 20′ (backing material 12′) (in the depth direction of FIG. 7) applies a primer material in Act 812 on the clean portion of the length of glass 20′ (backing material 12′) unwound therefrom to form the primer layer 26 as it passes thereunder. Optionally, prior to being coated with the material forming the primer layer 26, the portion of the length of glass 20′ (backing material 12′) can be cleaned in Act 804 and dried in Act 808 as it is unwound from the stock roll 70. Then, the primer application device 74 applies the primer layer material 44 to form the primer layer 26 to the just cleaned portion of the length of glass 20′ (backing material 12′) taken from the stock roll 70 in Act 812. Here, the distance from where the glass 20′ (backing material 12′) leaves the stock roll 70 to the location of the stamp chuck 32 and facing master chuck 30 is greater than the length, in the roll to roll direction of the portion of glass 20′ (backing material 12′) used to manufacture a pre-stamp 10′. As one portion of the glass 20′ (backing material 12′) is cleaned and coated, or simply coated, with the primer material, the previously primer material coated portion of the glass 20′ (backing material 12′) is moved between the stamp chuck 32 and the master chuck 40 and chucked to the stamp chuck in Act 814.

Once a master stamp template 30 receives a coating of a release layer 42 in Act 818 and a layer of the liquid PDMS forming the pattern material layer 44 thereon, it is mounted on the turntable and is indexed by the turntable 80 to be positioned and mounted on a master chuck 40 to be facing, and properly aligned to, the facing surface of the stamp chuck 32 in Act 816. This can be performed before or after the discrete portion 62 of the glass 20′ is positioned between the mater stamp template 30 and the stamp chuck 32 in Act 814. Alternatively, the master chuck 40 can be mounted to the turntable 80, such that the master stamp template 30 is replaced on the master chuck 40 while that is on the turntable 80. Vacuum is applied to the vacuum passages 52a-c in act 825, and the perimeter clamp 38 is raised to push the perimeter of the discrete portion 62 of the glass 20′ against the stamp chuck 30 in Act 826. The sequence of Acts 825 and 826 may be reversed.

After the primed surface of the portion of the glass 20′ (backing material 20′) is positioned and facing a master stamp template 30 and the perimeter clamp 38 is lifted from a location below the portion of the glass 20′ (backing material 20′) to extend along, and press, the perimeter of the portion of the glass 20′ (backing material 20′) on which the patterned layer 18 is to be formed against the perimeter of the stamp chuck 32 in act 824. Thereafter, the manufacture of the patterned layer follows a similar sequence to that shown and described with respect to FIGS. 3 to 4, wherein in Act 826 the coated surface of the glass, here glass 20′ (backing material 20′) is moved away from the stamp chuck 32 as shown and described with respect to FIGS. 4A to 4C hereof and into contact with the pattern material layer 44 in liquid form, in act 830 the pattern layer material 44 is cured by directing UV energy or light through the stamp chuck 32 and the glass 20′ (backing material 20′) into the pattern material layer 44 to cure, and in Act 834, the portion of the glass 20′ (backing material 12′) and the pattern layer thereof in removed from the master 20 with the patterned material layer 18 adhered thereto as shown and described with respect to FIGS. 4C to 4A hereof.

Once the portion of the glass 20′ (backing material 20′) just having had the patterned layer formed thereon is pulled from the master 20, vacuum in the passages 52a-c are relieved, and the stock roll 70 and take up roll 73 again moved in Act 800 to index a new discrete portion 62 of the glass 20′ (backing material 20′) to the position between the stamp chuck 32 and the current, or expected, location of a master 20 facing the stamp chuck 32, and the process repeated while the just formed pre-stamp moves toward the take up roll in act 838. The master stamp template 30 is than moved, by the turntable 80, out of alignment with the stamp chuck 32 in act 844, removed from the turntable and cleaned in Act 850, and again coated with the release layer 44 in act 818. The release layer 44 coated master stamp template 30 is then again coated with the pattern layer material 44 in act 822, and again mounted to a master chuck 40 in Act 823. The process of indexing the portion of the glass 20′ (backing material 12′), cleaning and recoating the masters, and positioning them to face the stamp chuck 32, is repeated until an entire roll of glass is coated with patterned layers 18, after which a new roll of glass 20 (backing material 12′) can be loaded into the apparatus and the process repeated. As stamp pre-forms 10′ composed of a portion of the glass 20′ (backing material 12′), the primer layer 26 and the patterned layer 18 are formed, and the stock roll 70 and take up roll 73 moved to index a new portion of the glass 20′ (backing material 20′) to the position between the stamp chuck 32 and the current, or expected, location of a master 20 facing the stamp chuck 32, the stamp pre-forms 10′ will become rolled into a the take up roll 73 which glass 20′ (backing material 12′) can be later rolled out, and individual stamps 10 formed therefrom.

In FIG. 8A, the actions required to singulate a stamp 10 from a sheet of glass having stamp pre-forms 101 thereon according to FIG. 9 hereof is shown. Here, the Act of FIG. 8, up to and including Act 834 are the same as those of FIG. 8. However, here, after the glass 20′ is moved away from the master stamp template 30 in Act 834, the glass 20′ forming a stamp pre-form 10′ is moved outwardly of the space between the stamp chuck 32 and the master stamp template 30 by rotation of the stock roller 70 and rollers 84a, b and 86a, b to be received on a support at Act 840. Then, a stamp separation device 90 is used to singulate the stamp 10 from the glass 20′ in Act 842, and stored on one of the sets of shelves 93a-c in a cassette 93 in Act 844.

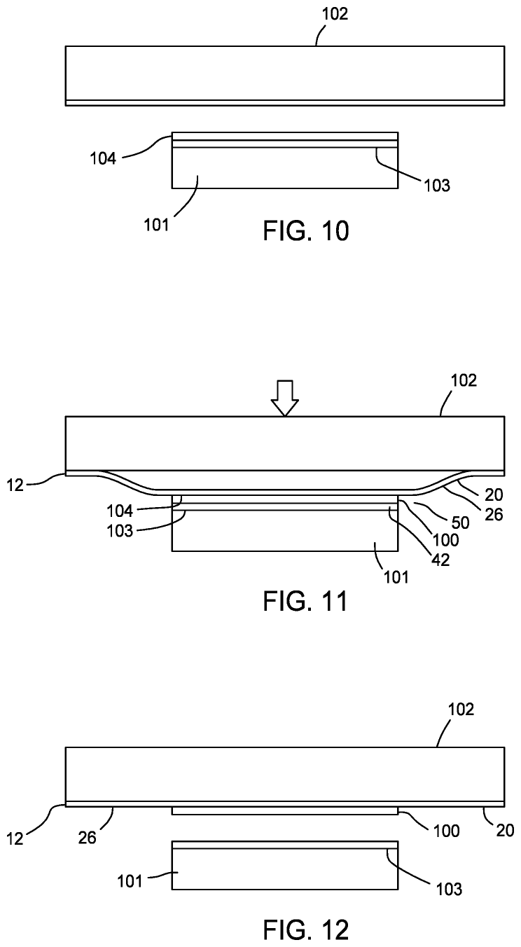

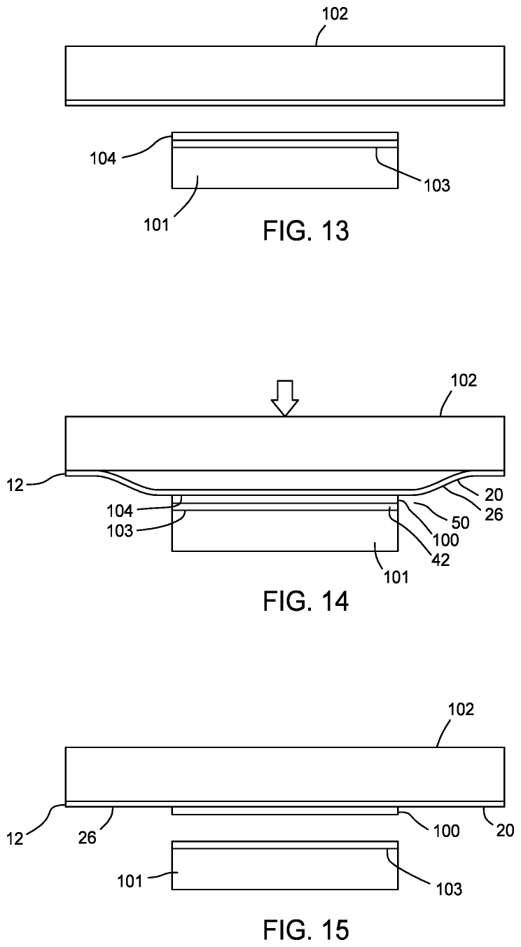

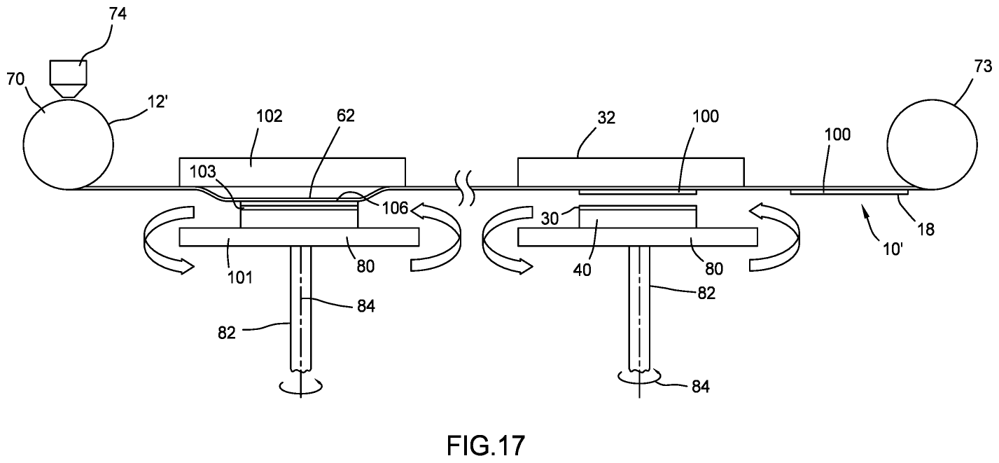

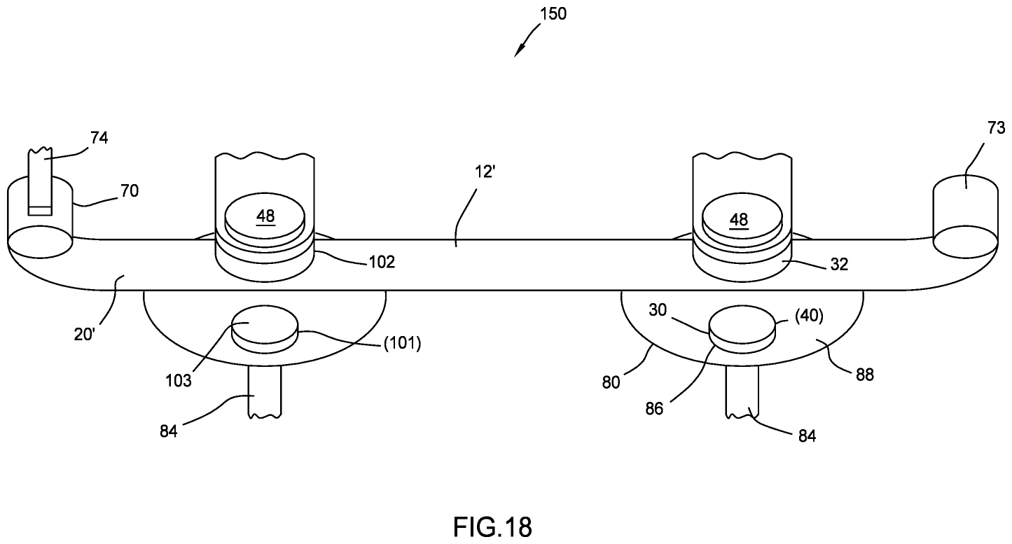

FIGS. 10 to 15 and 17 are schematic side views of representative equipment useful for manufacturing a cushioned stamp 10, i.e., one having a cushioning layer 100 between the backing material 12 and the patterned layer 18, including forming a cushioning layer 100 on the backing material 12, a patterned layer 18 having a desired pattern 19, the obverse of a pattern on a master stamp template 30, on the cushioning layer 100, wherein the cushioning layer 100 is formed on discrete portions of the backing material 12 on which the patterned layer 18 is to be formed. As shown in FIGS. 17 and 18, the stamp manufacturing apparatus 150 here is similar to that shown in FIG. 7 or 9, wherein glass 20′ in strip form, i.e. as unsingulated backing material 12′ is unwound from a stock roll 70 to incrementally move discrete portions 62 of the length of glass 20′ (backing material 12′) toward a take up roll 73. However, in contrast to the apparatus of FIGS. 7 and 9, here two sets of master chucks, with corresponding stamp glass chucks to hold and position the glass 20′ (backing material 12′) with respect thereto, are provided between the stock roll 70 and take up roll 73 (or between the stock roll 70 and a singulation device as described herein and shown schematically in FIG. 9), to first form the cushioning layer 100 on discrete portions of the glass 20′ (backing material 12′) and then form the patterned layer 18 on the cushioning layer 100. Once the patterned layer 18 is formed on the cushioning layer 100, a pre-stamp 10′ is formed, which can thereafter be cut from the length of glass 20′ (backing material 12′) to form a completed stamp 10.

To manufacture the pre-stamp 10′ having a cushioning layer 100, a blanking master chuck 101 for holding a cushioning layer master 103 and a master chuck 40 for holding a stamp master stamp template 30 are provided, and a blanking stamp chuck 102 facing the blanking master chuck 101 and the stamp chuck 32 facing the stamp master chuck 40 are provided in that physical order from the stock roll 70 to the take up roll 73 as shown in FIG. 17. Each of the stamp chuck 32 and the blanking stamp chuck 102 are configured to chuck a discrete portion of the length of glass 20′ (backing material 12′) on which a cushioning layer 100 and patterning layer 18 are to be sequentially formed, and each of the stamp chuck 32 and the blanking stamp chuck 102 have the structure and operational capability of the stamp chuck 32 shown in FIGS. 3 to 5 hereof and described herein with respect thereto, and they are provided between the stock roll 70 and take up roll 73 such that the length of glass 20′ (backing material 12′) passes thereunder.

Here, to form a pre-stamp 10′ having the cushioning layer 100, the stock roll 70 is rotated to unroll therefrom a discrete amount or discrete portion 62 of the length of glass 20′, the portion having a dimension, in the direction between the stock roll 70 and take up roll 73 encompassing slightly larger than the side dimensions of a competed stamp. For example, if the glass 20 (backing material 12) of a finished stamp is 15 inches long on each side thereof in the X and the Y directions, a discrete portion of the length of glass 20′ (backing material 12′) greater than 15 inches is unrolled from the stock roll 70, and taken up by the take up roll 73, such that a new or fresh discrete portion 62 of the length or strip of glass 20′ (backing material 12′) is positioned between the blanking master chuck 101 and the stamp cushion chuck, and a discrete portion 62 of the glass 20′ (backing material 12′) having a cushioning layer 100 previously formed thereon using the cushioning layer master 103, indexes into the space between the master chuck 40 and the stamp chuck 32. Here, to make a stamp 10 having a backing material 12 of side dimensions of for example 15 by 15 inches, the strip of glass, in the depth direction of FIG. 17 (into the page) is 15 inches. The length of the strip of glass 20′ (backing material 12′) on the stock roll 70 is preferably pre-cleaned before being rolled up to provide the stock roll 70, and as the stock roll 70 is unrolled, a primer application device 74 such as a sprayer bar extending across the width of the length of glass 20′ (backing material 12′) (in the depth direction of FIG. 17) applies a primer material on the clean portion of the length of glass 20′ (backing material 12′) unwound therefrom to form the primer layer 26 as it passes thereunder. Optionally, prior to being coated with the material forming the primer layer 26, the portion of the length of glass 20′ (backing material 12′) can be cleaned and dried as it is unwound from the stock roll 70. Then, the primer application device 74 applies the primer material to form the primer layer 26 to the just cleaned portion of the length of glass 20′ (backing material 12′) taken from the stock roll 70. Here, the distance from where the glass 20′ (backing material 12′) leaves the stock roll 70 to the location of the stamp cushion chuck 102 and facing master cushion chuck 101 is greater than the length of a discrete portion 62 of the glass 20′ (backing material 12′) on which the cushioning layer is to be formed, i.e., greater than the side dimension of the backing material 12 of a finished stamp 10. However, the gap between adjacent portions of the glass 20′ (backing material 12′) where the cushioning layer 100 and patterning layer 18 are form should be minimized, to avoid waste of the glass 20′ (backing material 12′). Thus, the center to center spacing between the master cushion chuck 102 and the master chuck 102 is a multiple of the side wall length of a finished stamp, for example 2 or three times that length, such that the portion of the glass 20′ (12′) between the stamp cushion chuck 102 and the master chuck 40, during the production of pre-stamps thereon, will include a number of cushioning layers thereon equal to the multiple of the side of the wall length minus 1. For example, if the multiple is two, then one cushioning layer 100 will be located on the portion of the glass 20′ (12′) between the stamp cushion chuck 102 and the master chuck 40, if the multiple if three, i.e., the center to center spacing between the master cushion chuck 102 and the master chuck 102 is three times the side length of a finished stamp, then two cushioning layers 100 will be located on the portion of the glass 20′ (12′) between the stamp cushion chuck 102 and the master chuck 40 during production of stamp preforms on the glass 20′ (backing layer 12′).

As one portion of the glass 20′ (backing material 12′) is cleaned and coated, or simply coated, with the primer material to form the primer layer 26 thereon, the previously primer material coated portion of the glass 20′ (backing material 12′) having the primer layer 26 thereon is moved between the stamp cushion chuck 102 and facing master cushion chuck 101, and, simultaneously, a discreet portion of the glass 20′ (backing layer 12′) having a cushioning layer 100 formed thereon, is moved between the stamp chuck 32 and the master chuck 40.

As with the device described with respect to FIGS. 3 to 5 hereof with respect to the cleaning and replacing of a master stamp template 30 used to form a patterning layer 18, after each use of the cushioning layer master 103 to form a thin, planar outer surface, cushioning layer 100 on a discrete portion of the glass 20′ (backing material 12′), the cushioning layer master 103 must be cleaned, recoated with the release layer, for example using the CVD chamber shown in FIG. 7A, and the material of the cushioning layer in its liquid, uncured form, using a spin coater such as spin coater 55 in FIG. 7A and repositioned for reuse to form another cushioning layer 100. Here, that is accomplished by mechanically moving the a cushioning layer master 103 having a blank surface formed on one surface side thereof, or the master chuck 101 with the cushioning layer master 103 thereon, to the side of the location of the stamp chuck 102, such as by mounting the cushioning layer master 103 or the master chuck 101 with the cushioning layer master thereon on a turntable 80 and rotating the turntable 80 between a location where the master is positioned facing the stamp cushion chuck 102 and a location where the cushioning layer master 103 is spaced from the stamp cushion chuck 102 and somewhat to the side thereof to enable removal of the cushioning layer master 103 without physical or mechanical interference with the stamp cushion chuck 102. For example, a turntable 80 having one or more master receiving stations 86 thereon or in a master chuck receiving surface thereof, can receive a cushioning layer 103 or a master cushion chuck 101, or a master chuck 40, at each receiving station. By rotating a shaft 82 connected to the center of the turntable 80 at the center thereof, about a centerline 84 of the shaft, the master receiving stations 86 can be moved in arcs to be positioned below and facing the stamp cushion chuck 102 and stopped thereat for the process of forming the cushioning layer 100 on the portion of the glass 20′ (backing material 12′) between that master 103 and the stamp cushion chuck 102, and then the turntable 80 can be indexed in another rotational motion about the axis 84 to position and fix an additional master cushion chuck 101 to face the stamp cushion chuck 102. Thus, by providing a plurality of identical cushioning layer masters 103, as each cushioning layer master 103 is used to form a cushioning layer 100 and moved away from the location of the stamp cushion chuck 102, a new cushioning layer master 103 having a blank surface one side thereof, with a release layer 42 and a layer of liquid PDMS as the cushioning layer material 104 thereon is indexed by the turntable 80 to be positioned facing, and properly aligned to, the facing surface of the stamp cushion chuck 102.

Once a cushioning layer master 103, with a release layer 42 and a layer of liquid PDMS as the cushioning layer material 104 thereon is indexed by the turntable 80 to be positioned facing, and properly aligned to, the facing surface of the stamp cushion chuck 102 and a portion of the primer coated glass 20′ (backing material 12′) is moved into the cushioning layer 100 forming apparatus with the primer layer 26 facing toward the master cushion chuck 101, the apparatus is ready to form a cushioning layer 100 on the portion of the glass 20′ (backing material 12′) underlying the stamp cushion chuck 102. At the same time, a cushioning layer master 103 which was just used to form a cushioning layer 100 and which was moved by the turntable 80 away from the location facing the stamp cushion chuck 102 is removed from a master cushion chuck 101 on the turntable 80 of the stamp forming apparatus, such as manually or by an automated methodology such as with a robot. A clean, and coated with the release layer 42 and cushioning layer material 104, cushioning layer master 103 is then located on the open master chuck 101. Alternatively, the just removed master 103 could be cleaned, recoated with the release layer 42, coated with a fresh cushioning material layer 104, and placed on the open master cushion chuck 101 from which it had been removed. After the new or previous cushioning layer master 103, coated with a new release layer 42 and a cushioning material layer 104 is located on the turntable 80, it may be moved to the location facing the stamp cushion chuck 102, a new or fresh discrete portion of the glass 20′ (backing material 12′) positioned therebetween, and a new cushioning layer 100 is formed on the discrete portion of the glass 20′ (backing material 12′) is formed thereon as described herein.

The stamp cushion chuck 102 has the same structure as the stamp chuck 32. Thus, similarly to the manufacture of the patterning layer 18 of the stamp 10 in FIGS. 3 to 6 hereof, here the cushioning layer 100 is formed on the glass 20 by first applying vacuum to the passages 52a, b in the stamp cushion chuck 102 to pull the discrete portion of the glass 20′ (backing material 12′) thereagainst, and the perimeter clamp 38 is pushed upwardly from a location below the portion of the glass 20′ (backing material 20′) to extend along, and press, the perimeter of the discrete portion 62 of the glass 20′ (backing material 20′) on which the cushioning layer 100 is to be formed, against the perimeter of the stamp cushion chuck 102. Thereafter, the manufacture of the cushioning layer 100 follows a sequence wherein the paradigm for positioning the primer coated surface of the discrete portion of the glass 20′ (backing layer 12′) in contact with the cushioning layer material 104 in liquid form, the curing thereof by directing UV energy or light through the stamp cushion chuck 102 and the glass 20′ (backing material 12′) into the cushioning layer material 104 to cure it, and the sequence of pulling the glass 20′ (backing material 12′) away from the master 101 with the newly formed cushioning layer 100 adhered thereto are performed.

Next the discrete portion of the glass 20′ (backing material 12′) having the cushioning layer is moved laterally toward the next set of facing chuck, the stamp chuck 32 and the master chuck 30, by the unrolling of the backing material 12′ roll 70 and taking up of the portion of the backing material 12′ having pre-stamps 10′ formed thereon by the take up roll 73. The patterned layer 18 of the pre-stamp 10′ is there formed over the cushioning layer 100 using the same sequence as those used to form the patterning layer in FIGS. 3 to 5, i.e., by first applying vacuum to the passages 52a, b in the stamp cushion chuck 102 to pull the discrete portion of the glass 20′ (backing material 12′) thereagainst, and the perimeter clamp 38 is pushed from a location below the discrete portion of the glass 20′ (backing material 12′) having the cushioning layer 100 generally centered thereon to press the perimeter of the discrete portion of the glass 20′ (backing material 12′) having the cushioning layer 100 on which the patterned layer 18 is to be formed against the perimeter of the stamp chuck 32. Thereafter, following the pressuring sequence of the region between the glass 20′ (backing material 12′) and the facing surface of the stamp chuck 32 as shown in FIGS. 3 to 5, the cushioning layer 100 is positioned in contact with the pattern material layer 44 in liquid form, and the pattern material layer 44 is cured by directing UV energy or light through the stamp chuck 32, the cushioning layer 100, and the glass 20′ (backing material 12′) into the pattern material layer 44, and thereafter the sequence of pulling the glass 20′ (backing material 12′) having the cushioning layer 100 and patterned layer 18 formed thereon to for a pre-stamp away from the master 20 with the patterned material layer 18 adhered thereto as described using sequential application of vacuum in the zones C to A of FIGS. 4A to 4C are performed.

Once the portion of the glass 20′ (backing material 12′) just having the patterned layer 18 formed thereon is pulled from the master 20, vacuum in the passages are relieved, and the stock roll 70 and take up roll 73 moved to index a new portion of the glass 20′ (backing material 12′) having the cushioning layer 100 thereon to the position between the stamp chuck 32 and the current, or expected, location of a master 20 facing the stamp chuck 32, and the process repeated. The process of indexing the portion of the glass 20′ (backing material 12′), cleaning and recoating the masters, and positioning them to face the stamp chuck 32, is repeated until an entire roll of glass is coated with cushioned layers 100 and patterned layers 18 thereover, after which a new roll of glass 20 (backing material 12′) can be loaded into the apparatus and the process repeated. As stamp pre-forms 10′ are formed, and the stock roll 70 and take up roll 73 moved to index a new discrete portion of the glass 20′ (backing material 12′) to the position between each set of chucks, the stamp pre-forms 10′ will become rolled into a roll which can be later rolled out, and individual stamps formed therefrom

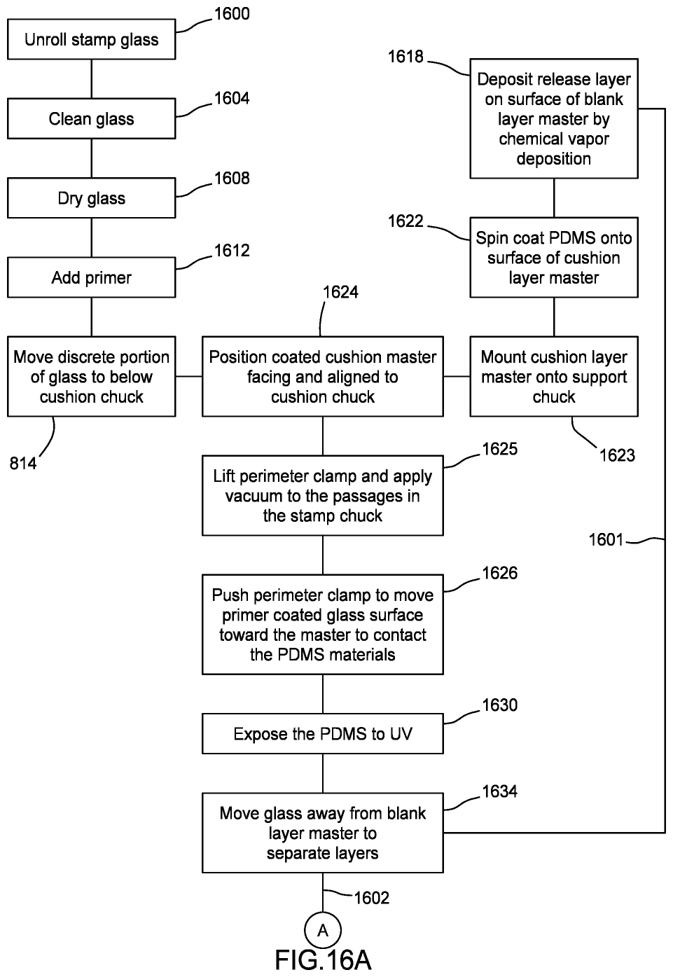

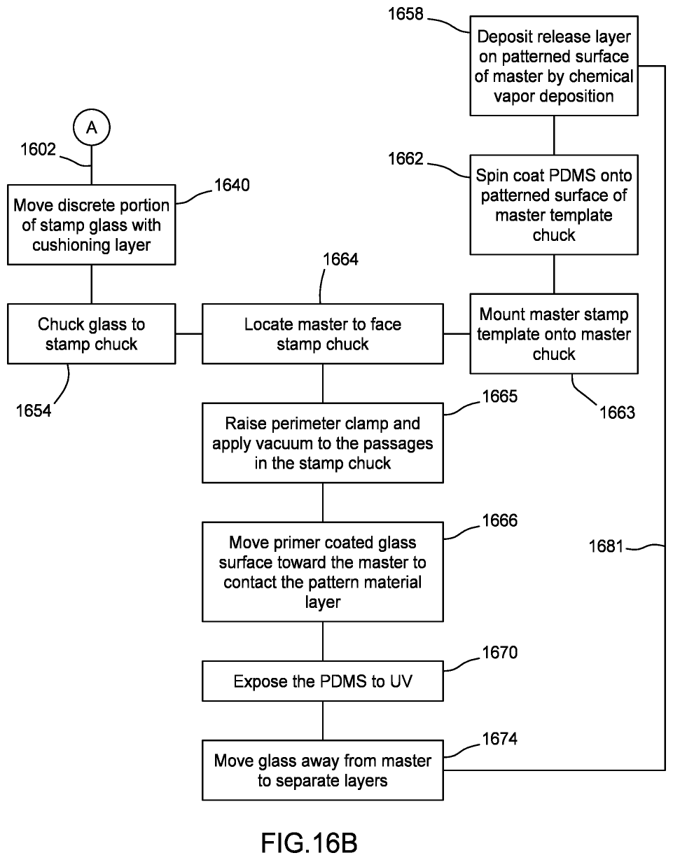

FIGS. 16A and 16B are a flowchart showing a series of activities for manufacturing a cushioned stamp 10 according to the sequence of processes described with respect to FIGS. 10-15 and 17. Here the backing material 12′, here thin stamp glass 20′ having a thickness on the order of 200 microns, is provided on a backing material supply or stock roll 70 wherein a length of glass 20′ (backing material 12′) equal to at least several pieces of the glass 20 in the X or Y directions of FIG. 1, and, after both a cushioning layer 100 and patterned layer 18 are formed on discrete portions thereof, the length of glass 20′ (backing material 12′) is moved toward a take up roll 73. The glass 20′ (backing material 12′) moves from the stock roll 70 to the take up roll 73 in discrete steps, separated in time, the physical length of the portion of the glass 20′ (backing material 12′) moved in each step a function of the distance from the pull out location of the glass 20′ (backing material 12′) from the stock roll 70 the location where the cushioning layer 100 is formed on a discrete portion thereof. Once both the cushioning layer 100 and the patterned layer 18 are formed on the discrete portion of the glass, a pre-stamp 10′ is formed, which can later be cut from the length of glass 20′ (backing material 12′) to form a finished stamp 10.

Here, to manufacture a pre-stamp, the stock roll 70 is rotated in Act 1600 to unroll therefrom a discrete amount or the portion of the length of glass 20. The length of glass 20′ (backing material 12′) on the stock roll may be pre-cleaned and dried before being rolled up to provide the stock roll 70, and as the stock roll 70 is unrolled in Act 1600, a primer application device 74 such as a sprayer bar extending across the width of the glass 20′ (backing material 12′) (in the depth direction of FIG. 17) applies a primer material in Act 1612 on the clean portion of the length of glass 20′ (backing material 12′) unwound therefrom to form the primer layer 26 as it passes thereunder. Optionally, prior to being coated with the material forming the primer layer 26, the portion of the length of glass 20′ (backing material 12′) can be cleaned in Act 1604 and dried in Act 1608 as it is unwound from the stock roll 70. Then, the primer application device 74 applies the primer material to form the primer layer 26 to the just cleaned portion of the length of glass 20′ (backing material 12′) taken from the stock roll 70 in Act 1612. Here, the distance from where the glass 20′ (backing material 12′) leaves the stock roll 70 to the location of the stamp cushion chuck 102 and facing master cushion chuck 101 is greater than the length, in the roll to roll direction of the discrete portion of glass 20′ (backing material 12′) used to manufacture a pre-stamp 10, and as one portion of the glass 20′ (backing material 12′) is cleaned and coated, or simply coated, with the primer material, the previously primer material coated portion of the glass 20′ (backing material 12′) is moved between the stamp cushion chuck 102 and the master cushion chuck 101 in Act 1614.

Once a cushioning layer master 103 receives a coating of a release layer 42 in Act 1618 and thereafter a layer of liquid cushion layer material 104, for example PDMS, thereon in Act 1622, the cushioning layer master 103 is positioned on a master cushion chuck 101 in Act 1623 and indexed by the turntable 80 to locate the release layer coated and cushioning layer material coated cushioning layer master 103 to be facing, and properly aligned to, the facing surface of the stamp cushion chuck 102 in Act 1624. Then, with the discrete portion 62 of the primer coated glass 20′ (backing material 12′) with the primer layer 26 thereof facing toward the master cushion chuck 101 with the cushioning material layer 104 thereon, the apparatus is ready to form a cushioning layer 100 on the discrete portion 62 of the glass 20′ (backing material 12′) underlying the stamp cushion chuck 102. At the same time, in Act 1601 a master 103 which was just used to form a cushioned layer 100 is removed using the turntable 80, cleaned, and coated with the release layer 42 and cushioning layer material 104, repeating Acts 1618 and 1622.

The cushioning layer 100 is formed by lifting the perimeter clamp 38 to push the perimeter for the discrete portion 62 of the glass against the stamp cushion chuck 102 and applying vacuum to pull the discreet portion of the glass 20 (backing material 12′) against the facing surface of the stamp cushion chuck 102 in Act 1626. Thereafter the primer coated surface of the glass 20′ (backing material 20′) is moved into contact with the cushioning material layer 104 in liquid form in Act 1626, and is cured in Act 1630 by directing UV energy or light through the stamp cushion chuck 102 and the glass 20′ (backing material 20′) into the cushion material layer 104 to cure the cushioning material layer 104 into the cushioning layer 100 in Act 1630, and the glass 20′ (backing material 20′) with the cushioning layer 100 thereon, is pulled away from the cushioning layer master 103 in Act 1634.

Once the portion of the glass 20′ (backing material 12′) just having the cushioning layer 100 formed thereon is pulled from the cushioning layer master 103, vacuum in the passages in the stamp cushion chuck 102 are relieved and the perimeter clamp 38 is withdrawn, and the stock roll 70 and take up roll 73 moved to index a new portion of the glass 20′ (backing material 20′) to the position between the stamp cushion chuck 102 and the current, or expected, location of a cushioning layer master 103 facing the stamp cushion chuck 102 and a discrete portion of the glass 20′ (backing material 12′) having a cushioning layer thereon is simultaneously moved to the region between the stamp chuck 32 and the master chuck 40 in Act 1640.

Once a master stamp template 30 receives a coating of a release layer 42 in Act 1658 and a layer of patterning layer material 44 thereover, for example a layer of liquid PDMS, in Act 1662, the master stamp template 30 is indexed by the turntable 80 to be positioned on a master chuck 40 in Act 1663 to be facing, and properly aligned to, the facing backing material chucking surface of the stamp chuck 32 in Act 1664.

The patterned layer 18 of the stamp preform 10′ is formed by raising the perimeter clamp 38 from a location below the portion of the glass 20′ (backing material 20′) to extend along, and press, the perimeter of the discrete portion of the glass 20′ (backing material 12′) having the cushioning layer 100 generally centered thereon against the perimeter of the stamp chuck 32 and applying vacuum to the passages 52a-c in the stamp chuck 32 to pull the stamp thereagainst in act 1655. Thereafter, the manufacture of the patterned layer 18 follows a similar sequence to that shown in FIGS. 3 to 5 and described herein with respect thereto, wherein cushioning layer 100 is moved into contact with the pattern material layer 44 in Act 1666, which is cured by directing UV energy or light through the stamp chuck 32 and the glass 20′ (backing material 20′), and the cushioning layer 100 and into the pattern material layer 44 Act 1670. Once the pattern material layer 44 is cured to form the patterned layer 18, the glass 20′ (backing material 20′) with the cushioning layer 100 and patterned layer 18 thereon are pulled away from the master 20 in Act 1674.

Once the portion of the cushioning layer 100 just having the patterned layer formed thereon is pulled from the master 20, vacuum in the passages are relieved, and the stock roll 70 and take up roll 73 moved to simultaneously index a new cushioning layer 100 layer to the position between the stamp chuck 32 and the current, or expected, location of a master 20 facing the stamp chuck 32 and a primer layer 26 coated discrete portion of the glass 20′ (backing material 12′) between the master cushion chuck facing the stamp cushion chuck 102 by moving the glass 20′(backing material 12′) in Act 1600, and the process repeated.

While the foregoing is directed to embodiments of the present disclosure, other and further embodiments of the disclosure may be devised without departing from the basic scope thereof, and the scope thereof is determined by the claims that follow.

What is claimed is:

1. An apparatus for manufacturing a nano-imprint lithography stamp from a master template stamp, comprising:
a stamp chuck configured to selectively secure a stamp backing material thereto;
a master chuck configured to support a master template stamp, the master template stamp including a master pattern thereon, the master chuck configured to support the master template stamp in facing relationship to the stamp backing material when selectively secured to the stamp chuck; wherein
the master template stamp includes an electromagnetic energy curable material on and in the master pattern; and
the stamp chuck is configured and arranged to position a portion of the backing material thereon spaced therefrom and in contact with the electromagnetic energy curable material, and the stamp chuck is further configured to position the portion of the backing material in contact with the energy curable material, after it is cured, in contact with the stamp chuck.

2. The apparatus of claim 1, further comprising a stock roll of a length of stamp backing material.

3. The apparatus of claim 2, further comprising a take up roll configured to receive stamp backing material thereon.

4. The apparatus of claim 3, wherein the length of stamp backing material extends between the master template stamp and the stamp chuck.

5. The apparatus of claim 4, wherein at least one of the stock roller and the take up roller is configured to move a discrete portion of the backing material in the direction between the stock roller and the take up roller.

6. The apparatus of claim 2, wherein the length of stamp backing material extends between the master template stamp and the stamp chuck; and
a singulation device is disposed adjacent to the master chuck, on the side thereof opposite to the stock roll.

7. The apparatus of claim 2, further comprising a cushioning layer master and a cushioning layer stamp chuck in facing relationship with one another, wherein the cushioning layer master and the cushioning layer stamp chuck are disposed between the stock roll and the master template chuck.

8. A method of manufacturing a nano-imprint lithography stamp from a master template stamp, comprising:
selectively securing a stamp backing material to a stamp chuck;
positioning a master template stamp on a master chuck, the master template stamp including a master pattern thereon, the master chuck configured to support the master template stamp in facing relationship to the stamp backing material when it is selectively secured to the stamp chuck;
including an electromagnetic energy curable material on and in the master pattern; and
positioning a portion of the backing material supported by the stamp chuck the portion spaced therefrom and in contact with the electromagnetic energy curable material and exposing the electromagnetic curable material to electromagnetic energy an curing the curable material to form a solid thereof, and
positioning the portion of the backing material in contact with the energy curable material, after it is cured, in contact with the stamp chuck.

9. The method of claim 8, further comprising:
prior to including the electromagnetic energy curable material on and in the master pattern, coating the master pattern with a release material; and
prior to securing the backing material to the stamp chuck, coating the backing material to be facing the master template chuck with a primer.

10. The method of claim 9, further comprising a stock roll of a length of stamp backing material.

11. The method of claim 10, further comprising a take up roll configured to receive stamp backing material thereon.

12. The method of claim 11, wherein the length of stamp backing material extends between the master template stamp and the stamp chuck.

13. The method of claim 12, wherein at least one of the stock roller and the take up roller is configured to move a discrete portion of the backing material in the direction between the stock roller and the take up roller.

14. The method of claim 10, wherein the length of stamp backing material extends between the master template stamp and the stamp chuck; and
a singulation device is disposed adjacent to the master chuck, on the side thereof opposite to the stock roll.

15. The method of claim 10, further comprising a cushioning layer master and a cushioning layer stamp chuck in facing relationship with one another, wherein the cushioning layer master and the cushioning layer stamp chuck are disposed between the stock roll and the master template chuck.

16. An apparatus for manufacturing a nano-imprint lithography stamp from a master template stamp, comprising:
a first stamp chuck configured to selectively secure a stamp backing material thereto;
a first master chuck configured to support a cushion master, the cushion master including a blank pattern thereon, the first master chuck configured to support cushion master in facing relationship to the stamp backing material when selectively secured to the first stamp chuck; wherein
the cushion master includes an electromagnetic energy curable material on and in the master blank pattern; and
the first stamp chuck is configured and arranged to position a portion of the backing material thereon spaced therefrom and in contact with the electromagnetic energy curable material, and the first stamp chuck is further configured to position the portion of the backing material in contact with the energy curable material, after it is cured, in contact with the first stamp chuck.
a second stamp chuck configured to selectively secure a stamp backing material thereto;
a second master chuck configured to support a master template stamp, the master template stamp including a master pattern thereon, the second master chuck configured to support the master template stamp in facing relationship to the stamp backing material when selectively secured to the second stamp chuck; wherein the master template stamp includes an electromagnetic energy curable material on and in the master pattern; and
the second stamp chuck is configured and arranged to position a portion of the backing material thereon spaced therefrom and in contact with the electromagnetic energy curable material, and the second stamp chuck is further configured to position the portion of the backing material in contact with the energy curable material, after it is cured, in contact with the second stamp chuck.

17. The apparatus of claim 16, further comprising a stock roll of a length of stamp backing material.

18. The apparatus of claim 17, further comprising a take up roll configured to receive stamp backing material thereon.

19. The apparatus of claim 18, wherein the length of stamp backing material extends between the cushion master and the stamp chuck.
